(19) United States
(12) Patent Application Publication
(10) Pub. No.: US 2007/0155055 A1
(43) Pub. Date: Jul. 5, 2007

(54) Method of dicing wafer and die

(75) Inventor: Se-young Yang, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/635,010

(22) Filed: Dec. 7, 2006

(30) Foreign Application Priority Data
Jan. 4, 2006 (KR) 10-2006-0000865

(51) Int. Cl. H01L 21/00

(52) U.S. Cl. 438/113

(57) ABSTRACT

Provided are a method of dicing a wafer, which reduces sectional cracking and chipping, and a die. According to the method, a DAF (die attach film) may be attached on a grinded backside of a wafer, and the DAF and the backside of the wafer may be sawed to a depth. The backside of the wafer may be attached to a ring mount blocked by a tape, and the wafer may be separated into a plurality of dies by applying stress on the wafer through the tape of the ring mount. Each of the dies may include a die adhesive dam formed naturally and may be used together with the DAF when a die is bonded.

### PRIORITY STATEMENT

This application claims priority under 35 U.S.C. §119 to Korean Patent Application No. 10-2006-0000865, filed on Jan. 4, 2006, in the Korean Intellectual Property Office (KIPO), the entire contents of which are incorporated herein by reference.

### BACKGROUND

1. Field

Example embodiments relate to a method of fabricating a semiconductor device and the semiconductor device. Other example embodiments relate to a method of dicing a wafer and a die.

2. Description of the Related Art

A wafer dicing process is a process performed between a pre-process called a wafer fabricating process and a post-process called an assembly process. In the wafer dicing process, a wafer on which a plurality of semiconductor chips and/or dies has been formed may be cut and divided into separate chips and/or dies. In a conventional wafer dicing process, a wafer may be cut along the scribe lines formed between dies on the wafer using a blade rotating at a higher speed and/or a laser beam with a predetermined or given energy. The conventional wafer dicing process of sawing an about 200-μm thin wafer into separate dies using a blade may cause undesirable edge cracking, chipping and/or sectional cracking, and thus may reduce the fracture strength (e.g., force of endurance against cracking) of the die. The die may be more easily broken by an external impact. The edge cracking of the wafer generated afterblade process may be due to vibration and frictional heat generated by a mechanical contact between the wafer and the blade.

Damage to the cut surface of the die may be minimized or reduced to enhance the fracture strength of the die. For that purpose, methods have been proposed to reduce the cutting speed and/or the thickness of the blade. There may be limitations in reducing the thickness of the blade. When the cutting speed is reduced, productivity of the dies may be reduced.

Other dicing processes using the blade before back grinding of the wafer may be proposed. The impact by the dicing may be reduced when using this method. The DBG method may have a limitation in that it may be more difficult to apply a conventional die attach film (DAF) process, and also may be difficult to maintain an accurate position of the die in a ring mount after the back grinding of the wafer. The ring mount supporting a conventional dice-processed wafer may be a type of semiconductor equipment that may include a ring of circular stainless steel having an inner lower side blocked by a tape. A wafer dicing method using a laser may be used because of mass production and relatively little damage to a cut surface. The wafer dicing method using the laser may have a different cutting process depending on a type of light source.

The dicing method using an infrared light source may perform a cutting process which illuminates a relatively high-powered laser on a local portion of the wafer to melt and evaporate the wafer relatively rapidly. Because the relatively high temperature laser is illuminated so as to melt the wafer, an area where the laser may be directly illuminated and the adjacent area, which are heat affected zones (HAZ), may be damaged, and thus there may be damage to the cut surface. To overcome this problem, a water jetting method may be used that jets water simultaneously while illuminating the laser. In this method, the water may be used as a waveguide of the laser. Additionally, a cooling process through the water may be performed during the melting and evaporating process of wafer, and thus the damage caused by a higher temperature may be minimized or reduced. There may be many limitations in aspects of mass productivity, accuracy, and manufacturing costs.

In a method using an ultraviolet (UV) light source, a cutting process may be performed with a relatively low power by adopting quantum energy that corresponds to a bonding energy between silicon atoms within the wafer. The method using the UV light source may have smaller heat affected zones (HAZ) and internal structure damage compared with the method using the infrared light source, but may have relatively little capability as to mass productivity and a roughly cracked side. Another method using the UV light source may be a fracture controlled method that focuses UV light on a predetermined or given internal portion of a wafer to cut the predetermined or given internal portion of the wafer, places the wafer on a ring mount, and applies stress on the wafer, thereby performing a cutting process. The fracture controlled method may have limitations to some extent in controlling an accurate focus-illumination of the UV light source.

In the laser cutting method, as a local portion of the wafer is exposed to a higher temperature regardless of a type of the light source, a partial portion of the die attach film (DAF) attached on the wafer may be molten and stick to the backside of the wafer. A die crack may occur because the die may be relatively sticky when picking up the die.

### SUMMARY

Example embodiments provide a method of dicing a wafer to minimize or reduce damage of a cut surface and allow a DAF to be applied easily and a die.

In accordance with example embodiments, a method of dicing a wafer may include attaching a DAF (die attach film) on a grinded backside of the wafer, sawing both the DAF and the backside of the wafer to a depth, attaching the backside of wafer to a ring mount having an internal lower side blocked by a tape and/or separating the wafer into a plurality of dies by applying stress to the wafer through the tape of the ring mount.

Attaching of the DAF may be performed by attaching a single DAF tape or removing a laminate tape through an UV illumination process after attaching a two-layered tape consisting of a DAF tape and the laminate tape. A blade may be used for equipment sawing the DAF. Stress may be applied on the wafer by applying tension on the tape of the ring mount. The stress applied on the wafer and a sawing depth may be quantitatively determined using a relationship with fracture toughness K_{IC} or stress intensity factor K_{I} of the wafer.

According to other example embodiments, a die may be provided. The die including a step difference between an uncut portion and a cut portion may be formed by sawing. The die may have the step difference between the uncut portion and the cut portion by the sawing, and the step difference may serve as a die adhesive block for preventing or retarding a liquid adhesive from flooding onto a top surface of the die when a die is bonded on a printed circuit board (PCB). According to example embodiments, the die may be formed to use the blade and thus the DAF may not be attached on a backside of the die. The DAF and the die may be attached on the PCB together.

### BRIEF DESCRIPTION OF THE DRAWINGS

Example embodiments will be more clearly understood from the following detailed description taken in conjunction with the accompanying drawings. FIGS. 1A-4 represent non-limiting, example embodiments as described herein.

FIGS. 1A-1E are diagrams illustrating a method of dicing a wafer according to example embodiments;

FIG. 2 is an enlarged view of a portion A in FIG. 1E;

FIGS. 3A and 3B are diagrams illustrating a method of applying stress on a wafer; and

FIG. 4 is a diagram illustrating a die according to example embodiments.

### DETAILED DESCRIPTION OF EXAMPLE EMBODIMENTS

Example embodiments will be described more fully hereinafter with reference to the accompanying drawings. Example embodiments may, however, be embodied in many different forms and should not be construed as being limited to the embodiments set forth herein. Rather, these embodiments are provided so that this disclosure will be thorough and complete, and will fully convey the scope of example embodiments to those skilled in the art. In the drawings, the forms of elements are exaggerated for clarity. To facilitate understanding, identical reference numerals have been used, where possible, to designate identical elements that are common to the figures.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

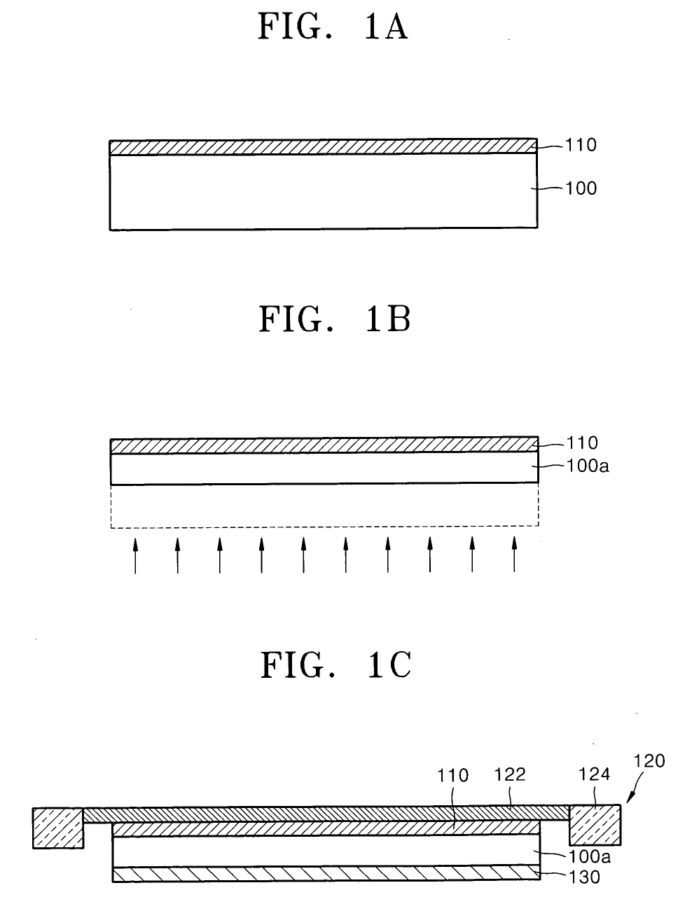

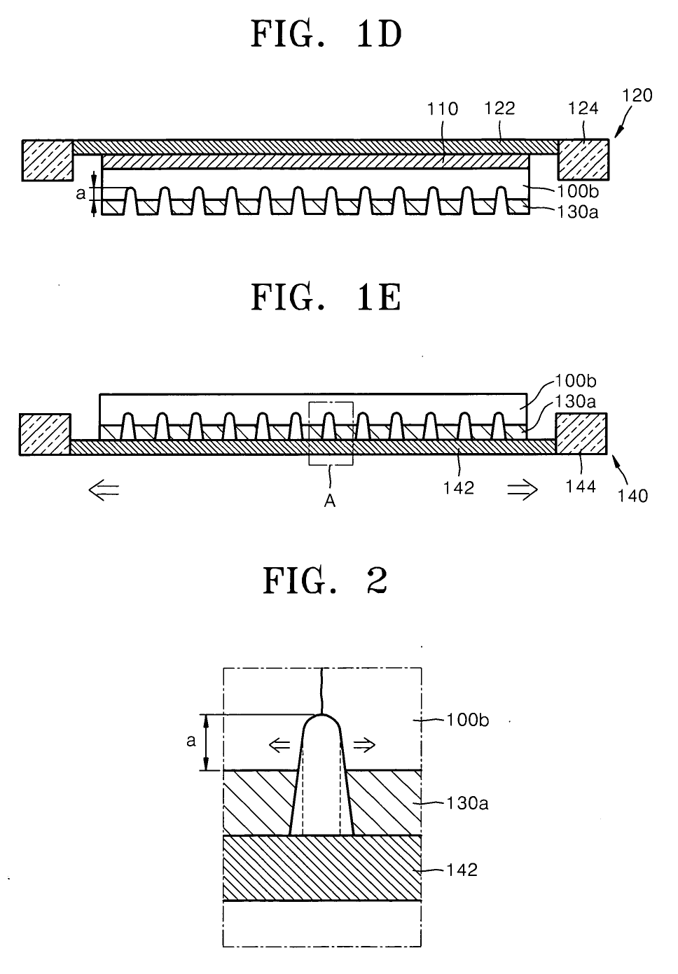

FIGS. 1A-1E are diagrams illustrating a method of dicing a wafer according to example embodiments. Example embodiments adopt a sawing and crack controlled method that saws the backside of a wafer and applies tension on the wafer to dice the wafer into a plurality of dies.

Referring to FIG. 1A, a tape 110 may be attached on a wafer 100 to protect an active region on a top side of the wafer 100. The tape 110 may be a laminate film and/or laminate tape. The tape 110, which may be a UV tape used in an UV illumination process, may separate the tape 110 from the wafer 100 after processes. The tape attaching process may be performed to protect the top side of the wafer 100 during a back grinding process that follows the tape attaching process because an active region may be formed on the top side. When there are other methods to protect the top side of the wafer 100, the tape attaching process may be replaced by other method.

Referring to FIG. 1B, a predetermined or given portion of a backside (in an arrow direction) of the wafer 100 may be removed by a back grinding process after the tape attaching process. The backside of the wafer 100 may be an opposite side of the wafer 100 where the active region is formed. In this back grinding process, an unnecessary layer may be removed from the backside of the wafer to minimize or reduce thickness of the wafer. This process may be required to manufacture a thin wafer having a thickness less than about 200 μm. Each of the dies contained in the wafer 100a after the back grinding process may be used to form a semiconductor chip.

Referring to FIG. 1C, a ring mount 120 may be attached to the laminate tape 110 on the top side of the wafer 100a in order to fix the wafer 100a. A die attach film (DAF) 130 may be attached to the backside of the wafer 100a. The ring mount 120 may include a stainless ring 124 that may be wider than the wafer 100a, and a tape 122 blocking an inner lower side of the ring mount 120. The laminate tape 110 on the top side of the wafer 100a may be attached to the tape 122 of the ring mount 120 so that the wafer 100a may be fixed. The tape 122 of the ring mount 120 may also be a laminate tape and may be attached to the laminate tape 110 of the top side of the wafer 100a. It may be possible to remove the laminate tape 110 attached on the top side of the wafer 100a and directly attach the wafer 100a on the tape 122 of the ring mount 120.

The DAF 130 attached on the backside of the wafer 100a may be similar to the laminate tape 110 protecting the top side of the wafer, but may have a thickness different from that of the laminate tape 110. This difference may be due to the purpose of use. A DAF and/or a DAF tape may be introduced to replace a liquid adhesive which contaminates a top side of a die when a die may be bonded on a printed circuit board (PCB). The DAF and/or the DAF tape may be a tape attached on the backside of the wafer and this tape may be cut together with the die when a dicing process is performed on the wafer in order to directly attach the die to the PCB without the liquid adhesive. Accordingly, the DAF may be thinner than a general tape for protecting the wafer's top side.

A DAF attaching process may use a single DAF tape similar to the laminate tape attaching process of the back grinding process and/or the DAF attaching process may be performed by removing only a laminate tape through a UV illumination process after attaching a UV tape, which may be a two-layered tape consisting of the DAF tape and the laminate tape, on the backside of the wafer.

Referring to FIG. 1D, a sawing process may be performed on the DAF 130 and the backside of the wafer 100a after the DAF 130 is attached. The DAF 130a may be separated into each part corresponding to each die. The wafer 100b may not be completely separated because only a partial portion of the wafer may be cut by the sawing process. The sawing process may use the blade and/or cutting method that prevents or retards attaching of the DAF. The depth of the backside of the wafer 100b that is cut by the sawing process may be determined by a stress intensity factor. The stress intensity factor will be described in more detail with reference to FIG. 2.

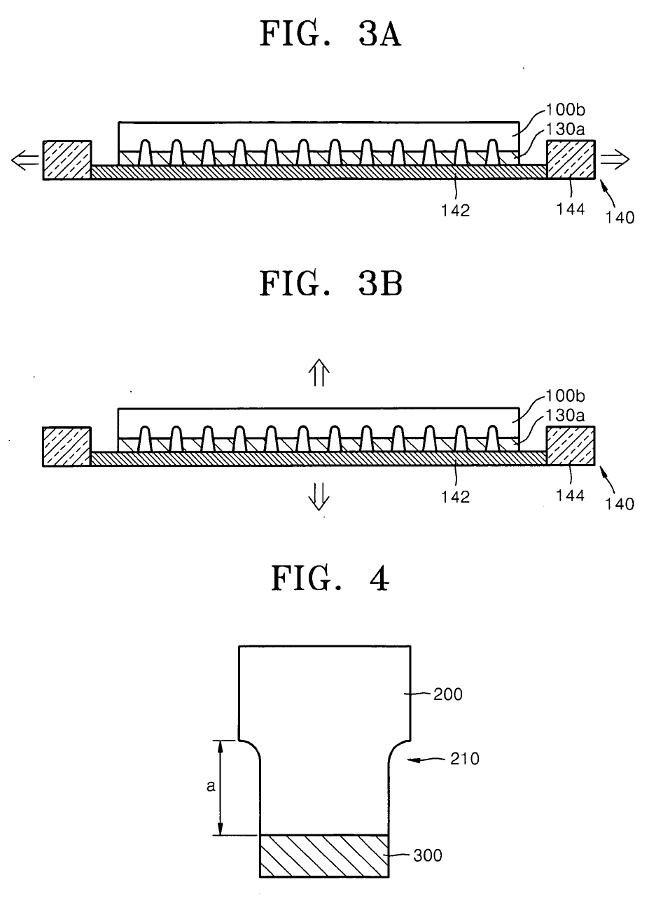

Referring to FIG. 1E, the laminate tape 110 and the ring mount 120 may be detached from wafer 100b after the sawing process, and a ring mount 140 may be attached to the DAF 130a of the backside of the wafer 100b. The ring mount 140 may be the same ring mount which was used as the ring mount 120 attached to the top side of the wafer. The wafer may be diced into a plurality of dies by applying stress (denoted by an arrow) on the wafer 100b after the ring mount 140 is attached on the DAF 130a. The ring mount 140 may include a stainless ring 144. Tension may be applied to the tape 142 of the ring mount 140 so that the stress may be applied on the wafer 100b. The more detailed description will be described with reference to FIGS. 3A and 3B.

Example embodiments adopt the sawing and fracture controlled method which may include steps of attaching the DAF to the backside of the wafer, cutting the backside of the wafer to a predetermined or given depth by sawing, and applying stress on the wafer to perform a dicing process on the wafer. A sectional cracking and/or a chipping caused in the conventional dicing method may be reduced. Additionally, because the laser is not used, the DAF on the die may be maintained without melting.

FIG. 2 is an enlarged view of a portion A in FIG. 1E. The wafer 100b, the DAF 130a, and the tape 142 of the ring mount may be illustrated in FIG. 2. The wafer 100b may be sawed to a predetermined or given depth from the backside of the wafer 100b. Stress (denoted by an arrow) may be applied to the sawed portion to generate cracks toward the top side of the wafer 100b, so that the wafer 100b may be separated into a plurality of dies. The sawing depth and applied stress may be determined by K_{I} called a stress intensity factor. The stress intensity factor K_{I} may be a fracture parameter used in fracture mechanics, and may be expressed by Equation 1 below when the stress intensity factor is applied to the sawed wafer 100b.

K_{I}=σ(π a)^{1/2} Equation 1

where, σ represents stress applied on the wafer, and a represents a sawing depth of the backside of the wafer, for example, an initial crack.

A relationship between fracture toughness K_{IC}, which is a physical property of a material, and the stress intensity factor may be expressed by Equation 2 below. A following relationship is satisfied for silicon such as a wafer.

K_{I}≈K_{IC} Equation 2

Referring to Equation 2, it may be revealed that abrupt brittleness fracture is induced when the stress intensity factor reaches the fracture toughness. The sawing depth of the wafer and the stress applied to the wafer for separating the wafer into a plurality of dies may be determined through Equation 1. It may be known that the applied stress has more influence on the stress intensity factor than the sawing depth. Two factor values may be appropriately selected with consideration of the stress that may be uniformly applied to the wafer and the sawing depth that minimizes or reduces a cutting defect.

FIGS. 3A and 3B are diagrams illustrating a method of applying stress on a wafer. Referring to FIG. 3A, the stress may be applied to the wafer 100b by applying tension on the tape 142 of the ring mount 140 to which the wafer 100b and the DAF 130a are attached. One method of applying the stress may be to stretch a ring 144 of the ring mount 140 in the outer direction (denoted by an arrow). Accordingly, the stress may be applied to the tape 142 and stress may be applied to the wafer 100b attached to the tape 142.

Referring to FIG. 3B, another method of applying the stress to the wafer 100b may be to pull the tape 142 in a vertical direction. The stress may be applied to the wafer 100b as the tape 142 is warped. The method of pulling the tape 142 in the vertical direction may be performed by providing a sealed device under the ring mount 140 to perform vacuum suction and/or inspire air. The method of pulling the tape in the vertical direction and the method of stretching the ring 144 in the outer direction in FIG. 3A may be performed simultaneously. In addition to the methods in FIGS. 3A and 3B, various methods of applying stress on the wafer may be used in example embodiments.

FIG. 4 is a diagram illustrating a die according to example embodiments. Referring to FIG. 4, a die 200 may be formed using the method of dicing the wafer according to example embodiments and a DAF 300 may be attached to the backside of the die 200. The die 200 may include a step difference 210 between a cut portion and an uncut portion formed by the sawing process. This step difference 210, for example, a die adhesive dam 210, may prevent or retard a liquid adhesive from flooding onto the top surface of the die when a die is bonded on a PCB. According to the conventional art, the die adhesive dam may be separately formed on the top side of the die to prevent or retard an overflow of the liquid adhesive. According to example embodiments, the die adhesive dam 210 may be formed without additional processes when the die is formed using the sawing process.

Because the die 200 is used together with the DAF 300 attached on the backside of the die 200 when the die 200 is bonded on the PCB, the die 200 may be relatively advantageous when a die bonding process is performed using only the DAF 300. Because the die is formed to use the sawing and the fracture controlled method, the sectional cracking and/or chipping may be reduced and/or the fracture intensity of the die may be improved.

According to example embodiments, the wafer dicing method may reduce the sectional cracking and chipping by applying the sawing and fracture controlled method. The fracture intensity (e.g., force of endurance against cracking) of the die may be improved. Additionally, because the die according to example embodiments has the die adhesive dam naturally formed through the sawing process, it may not be required to separately form the die adhesive dam on the top side of the die.

While example embodiments have been particularly shown and described with reference to example embodiments thereof, it will be understood by those of ordinary skill in the art that various changes in form and details may be made therein without departing from the spirit and scope of the following claims.

What is claimed is:

1. A method of dicing a wafer, the method comprising:
attaching a DAF (die attach film) on a grinded backside of the wafer;
sawing both the DAF and the backside of the wafer to a depth;
attaching the backside of wafer to a ring mount blocked by a tape; and
separating the wafer into a plurality of dies by applying stress to the wafer through the tape of the ring mount.

2. The method of claim 1, further comprising:
attaching a laminate tape on a top side of the grinded wafer before attaching a DAF.

3. The method of claim 2, further comprising:
attaching a ring mount on the laminate tape to support the wafer before attaching a DAF.

4. The method of claim 3, wherein after sawing the DAF, the laminate tape and the ring mount are detached from the wafer.

5. The method of claim 1, wherein the stress is generated by applying tension on the tape of the ring mount.

6. The method of claim 5, wherein the tension applied to the tape is generated by stretching the tape in an outer direction or pulling the tape in a vertical down direction.

7. The method of claim 1, wherein the tape of the ring mount is an UV (ultraviolet) tape removed using an UV illumination process.

8. The method of claim 1, wherein attaching the DAT includes at least one of attaching a single DAF tape and removing a laminate tape through an UV illumination process after attaching a two-layered tape consisting of a DAF tape and the laminate tape.

9. The method of claim 1, wherein the depth in sawing the DAF and the stress applied in separating the wafer are determined by a stress intensity factor K_{I} which is a fracture mechanics factor of the sawn wafer.

10. The method of claim 9, wherein the K_{I} is expressed as K_{I}=σ(π a)^{1/2} where σ represents stress applied on the wafer through the tape, and a represents the depth, and the σ and the a are determined by applying an intrinsic fracture toughness K_{IC} of the wafer to the K_{I}.

11. The method of claim 1, wherein each of the dies separated during the separating of the wafer includes a die adhesive dam formed on a cut portion due to the sawing.

12. The method of claim 11, wherein the die adhesive dam serves to prevent an adhesive used when a die is bonded from flooding onto a top surface of the die.

13. The method of claim 1, wherein each of the dies separated during the separating of the wafer is used for bonding a die together with the DAT attached on the backside of the die.

14. The method of claim 1, wherein the sawing is performed using a blade or a cutting method.

15. A die fabricated using the method of claim 1, the die including a step difference between an uncut portion and a cut portion formed by the sawing.

16. The die of claim 14, wherein the step difference serves as a die adhesive dam to prevent an adhesive used when the die is bonded from flooding onto a top surface of the die.

17. The die of claim 14, wherein the depth and stress are determined by a stress intensity factor K_{I} which is a fracture mechanics factor of the sawn wafer.

18. The die of claim 16, wherein the K_{I} is expressed as K_{I}=σ(π a)^{1/2} where σ represents stress applied on the wafer through the tape, a represents the depth, and the σ and the a are determined by applying a fracture toughness K_{IC} of the wafer to the K_{I}.

19. The die of claim 14, wherein the die is used for bonding a die together with the DAF attached on the backside of the die.

20. A die including a step difference between an uncut portion and a cut portion.
